(19) United States
(12) Patent Application Publication
(10) Pub. No.: US 2016/0240264 A1
(43) Pub. Date: Aug. 18, 2016

(54) SEMICONDUCTOR MEMORY DEVICE

(71) Applicant: KABUSHIKI KAISHA TOSHIBA, Tokyo (JP)

(72) Inventor: Koji HOSONO, Fujisawa Kanagawa (JP)

(21) Appl. No.: 15/046,231

(22) Filed: Feb. 17, 2016

(30) Foreign Application Priority Data
Feb. 18, 2015 (JP) 2015-029644

(51) Int. Cl. G11C 16/34; G11C 16/10

(52) U.S. Cl. CPC G11C 16/3459; G11C 16/10

(57) ABSTRACT

A semiconductor memory device includes a first memory cell, a first word line electrically connected to a gate of the first memory cell, a first bit line electrically connected to one end of the first memory cell, and a controller configured to execute a write operation, which includes a first cycle and a second cycle that is executed after the first cycle. The first cycle includes a first operation of applying a program voltage to the first word line, a second operation executed after the first operation of applying a first voltage to the first bit line and a second voltage lower than the first voltage to the first word line, and a third operation executed after the second operation of applying a verify voltage to the first word line. The second cycle includes the first operation and then the third operation, and excludes the second operation.

### CROSS-REFERENCE TO RELATED APPLICATION

This application is based upon and claims the benefit of priority from Japanese Patent Application No. 2015-029644, filed Feb. 18, 2015, the entire contents of which are incorporated herein by reference.

### FIELD

Embodiments described herein relate generally to a semiconductor memory device.

### BACKGROUND

A NAND-type flash memory in which memory cells are arranged in three dimensions has been known.

### DESCRIPTION OF THE DRAWINGS

FIG. 1 is a block diagram illustrating a configuration of a semiconductor memory device according to a first embodiment.

FIG. 2 is a perspective view and top view of a part of a memory cell array in the first embodiment.

FIG. 3 is a cross-sectional view of one memory cell transistor in the first embodiment.

FIG. 4 is a circuit diagram of a row-system circuit in the first embodiment.

FIG. 5 is a diagram of voltage waveforms of a write operation and a shape of a threshold shift in the first embodiment.

FIG. 6 is a conceptual diagram illustrating a weak erase operation in the first embodiment.

FIG. 7 is a diagram illustrating voltage waveforms of a weak erase operation and a program verify operation of a first example in the first embodiment.

FIG. 8 is a diagram illustrating voltage waveforms of a weak erase operation and a program verify operation of a second example in the first embodiment.

FIG. 9 is a diagram illustrating voltage waveforms of a weak erase operation and a program verify operation of a third example in the first embodiment.

FIG. 10 is a diagram illustrating a write cycle in a comparison example.

FIG. 11 is a diagram of voltage waveforms of a write operation and a shape of threshold shift in the comparison example.

FIG. 12 is a diagram illustrating a shape of a threshold shift of a memory cell generated after the write operation in the comparison example.

FIG. 13 is a diagram illustrating a write operation to a non-selected sub-block according to a second embodiment.

FIG. 14 is a diagram illustrating voltage waveforms of a write cycle of a first example in the second embodiment.

FIG. 15 is a diagram illustrating voltage waveforms of a write cycle of a second example in the second embodiment.

FIG. 16 is a diagram illustrating a write operation to a non-selected sub-block in a third embodiment.

FIG. 17 is a diagram illustrating voltage waveforms of a write cycle of a first example in the third embodiment.

FIG. 18 is a diagram illustrating voltage waveforms of a write cycle of a second example in the third embodiment.

### DETAILED DESCRIPTION

Embodiments now will be described more fully hereinafter with reference to the accompanying drawings. In the drawings, the thickness of layers and regions may be exaggerated for clarity. Like numbers refer to like elements throughout. As used herein the term “and/or” includes any and all combinations of one or more of the associated listed items and may be abbreviated as “/”.

The terminology used herein is for the purpose of describing particular embodiments only and is not intended to be limiting of the invention. As used herein, the singular forms “a,” “an” and “the” are intended to include plural forms as well, unless the context clearly indicates otherwise. It will be further understood that the terms “comprises,” “comprising,” “having,” “includes,” “including” and/or variations thereof, when used in this specification, specify the presence of stated features, regions, steps, operations, elements, and/or components, but do not preclude the presence or addition of one or more other features, regions, steps, operations, elements, components, and/or groups thereof.

It will be understood that when an element such as a layer or region is referred to as being “on” or extending “onto” another element (and/or variations thereof), it may be directly on or extend directly onto the other element or intervening elements may also be present. In contrast, when an element is referred to as being “directly on” or extending “directly onto” another element (and/or variations thereof), there are no intervening elements present. It will also be understood that when an element is referred to as being “connected” or “coupled” to another element (and/or variations thereof), it may be directly connected or coupled to the other element or intervening elements may be present. In contrast, when an element is referred to as being “directly connected” or “directly coupled” to another element (and/or variations thereof), there are no intervening elements present.

It will be understood that, although the terms first, second, etc. may be used herein to describe various elements, components, regions, layers and/or sections, such elements, materials, regions, layers and/or sections should not be limited by these terms. These terms are only used to distinguish one element, material, region, layer or section from another element, material, region, layer or section. Thus, a first element, material, region, layer or section discussed below could be termed a second element, material, region, layer or section without departing from the teachings of the present invention.

Relative terms, such as “lower”, “back”, and “upper” may be used herein to describe one element's relationship to another element as illustrated in the Figures. It will be understood that relative terms are intended to encompass different orientations of the device in addition to the orientation depicted in the Figures. For example, when the structure in the Figure is turned over, elements described as being on the “backside” of substrate would then be oriented on “upper” surface of the substrate. The exemplary term “upper”, may therefore, encompasses both an orientation of “lower” and “upper,” depending on the particular orientation of the figure. Similarly, when the structure in one of the figures is turned over, elements described as “below” or “beneath” other elements would then be oriented “above” the other elements. The exemplary terms “below” or “beneath” may, therefore, encompass both an orientation of above and below.

Embodiments are described herein with reference to cross section and perspective illustrations that are schematic illustrations of the embodiments. As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated, typically, may be rounded. Thus, the regions illustrated in the figures are schematic in nature and their shapes are not intended to illustrate the precise shape of a region and are not intended to limit the scope of the present invention.

Embodiments described herein provide a semiconductor memory device that may improve operational reliability.

In general, according to one embodiment, a semiconductor memory device includes a first memory cell, a first word line electrically connected to a gate of the first memory cell, a first bit line electrically connected to one end of the first memory cell, and a controller configured to execute a write operation, which includes a plurality of cycles including a first cycle and a second cycle that is executed after the first cycle. The first cycle includes a first operation of applying a program voltage to the first word line, a second operation executed after the first operation of applying a first voltage to the first bit line and a second voltage lower than the first voltage to the first word line, and a third operation executed after the second operation of applying a verify voltage to the first word line. The second cycle includes the first operation and then the third operation, and excludes the second operation.

Hereinafter, the embodiments will be described with reference to the drawings. Moreover, in the following description, common reference numerals are given to elements having the same functions and configurations. Hereinafter, as an example of the semiconductor memory device, a three-dimensional stacked NAND-type flash memory in which memory cells are stacked above the semiconductor memory device will be described.

### 1. First Embodiment

A semiconductor memory device according to the first embodiment will be described.

1.1 Configuration of Semiconductor Memory Device

1.1.1 Entire Configuration

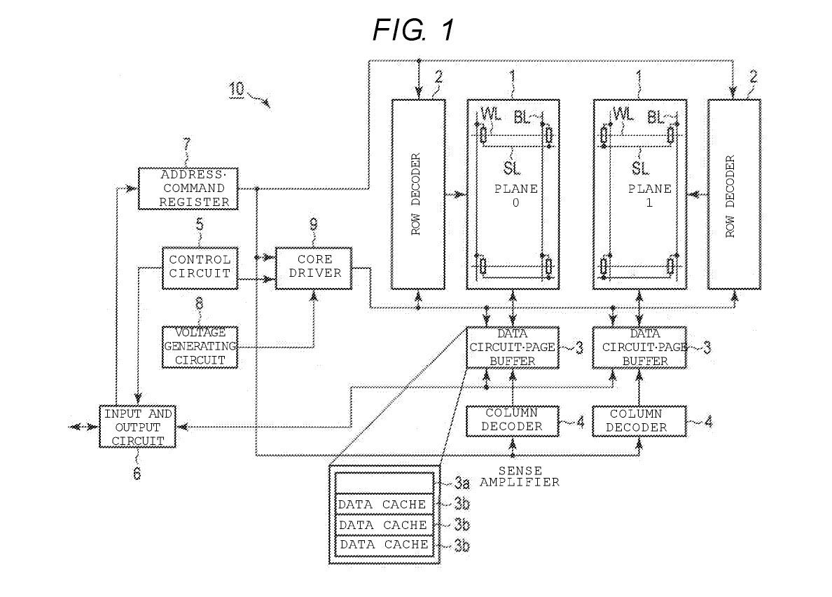

FIG. 1 illustrates a configuration of a semiconductor memory device 10 according to the embodiment. Each functional block may be achieved as one of hardware and computer software or a combination of both. Thus, generally, each block is described below in terms of functionality thereof so as to make clear that each block is any of these. Furthermore, it is not essential for each functional block to be distinguished as in the following examples. For example, a part of functions may be achieved by another functional block different from an exemplified functional block. Furthermore, the exemplified functional block may be divided into smaller functional sub-blocks

As illustrated in FIG. 1, the semiconductor memory device 10 includes a memory cell array 1, a row decoder 2, a data circuit•page buffer 3, a column decoder 4, a control circuit 5, an input and output circuit 6, an address•command register 7, a voltage generating circuit 8, and a core driver 9.

The semiconductor memory device 10 includes a plurality of memory cell arrays (here, two memory cell arrays are illustrated) 1. The memory cell array 1 may be referred to as a plane. The memory cell array 1 includes a plurality of blocks (memory blocks). Each block includes a plurality of memory cells, word lines WL, bit lines BL, and the like. A storage space including a certain plurality of memory cells forms one or a plurality of pages. Data is read and written on a page basis. Details of the memory cell array 1 will be described later.

A set including the row decoder 2, the data circuit•page buffer 3, and the column decoder 4 is provided for each memory cell array 1. The row decoder 2 receives a block address signal and the like from the address•command register 7 and receives a word line control signal or a select gate line control signal from the core driver 9. The row decoder 2 selects a block, a word line, and the like based on the received the block address signal, the word line control signal, and the select gate line control signal.

The data circuit•page buffer 3 temporarily holds data read from the memory cell array 1, and receives write data from outside of the semiconductor memory device 10, and writes the data received in a selected memory cell. The data circuit•page buffer 3 includes a sense amplifier 3a. The sense amplifier 3a includes a plurality of sense amplifier circuits respectively connected to a plurality of bit lines BL and amplifies a potential of the bit line BL. As described above, data unit that is read or written simultaneously by the sense amplifier 3a is referred to as a page and a data size is referred to as a page length. For example, the page length is 16 kBytes.

For example, the semiconductor memory device 10 may hold two or more bits of data in one memory cell. Thus, for example, the data circuit•page buffer 3 includes three data caches 3b. Since each data cache may be operated in a data size of the same page length as that of the sense amplifier 3a, for example, when the page length is 16 kBytes, each data cache includes a number of latch circuits sufficient to store 16 kBytes. A first data cache 3b temporarily holds one of a lower page data and an upper page data, and a second data cache 3b temporarily holds the other of the lower page data and the upper page data. Here, the lower page data corresponds to data of one page of a lower bit when multi-value data of the two-bit/cell is stored. Furthermore, the upper page data corresponds to data of one page of an upper bit of the two-bit/cell. The upper page data includes an upper bit set of each two-bit data of a plurality of related memory cells. For example, a third data cache 3b temporarily holds data that is rewritten in the memory cell based on a result of verify reading.

The column decoder 4 receives a column address signal from the address•command register 7 and decodes the received column address signal. The column decoder 4 controls an input and output of data in the data circuit•page buffer 3 based on a decoded address signal.

The control circuit 5 receives commands instructing regarding read, write, erase, and the like from the address•command register 7. The control circuit 5 controls the voltage generating circuit 8 and the core driver 9 according to a predetermined sequence based on the instruction of the command. The voltage generating circuit 8 generates various voltages according to an instruction of the control circuit 5. The core driver 9 controls the row decoder 2 and the data circuit•page buffer 3 to control the word lines WL and the bit lines BL according to an instruction of the control circuit 5. The input and output circuit 6 controls an input of the command, the address, and the data from outside of the semiconductor memory device 10 or outputs the data to outside of the semiconductor memory device 10.

1.1.2 Configuration of Memory Cell Array

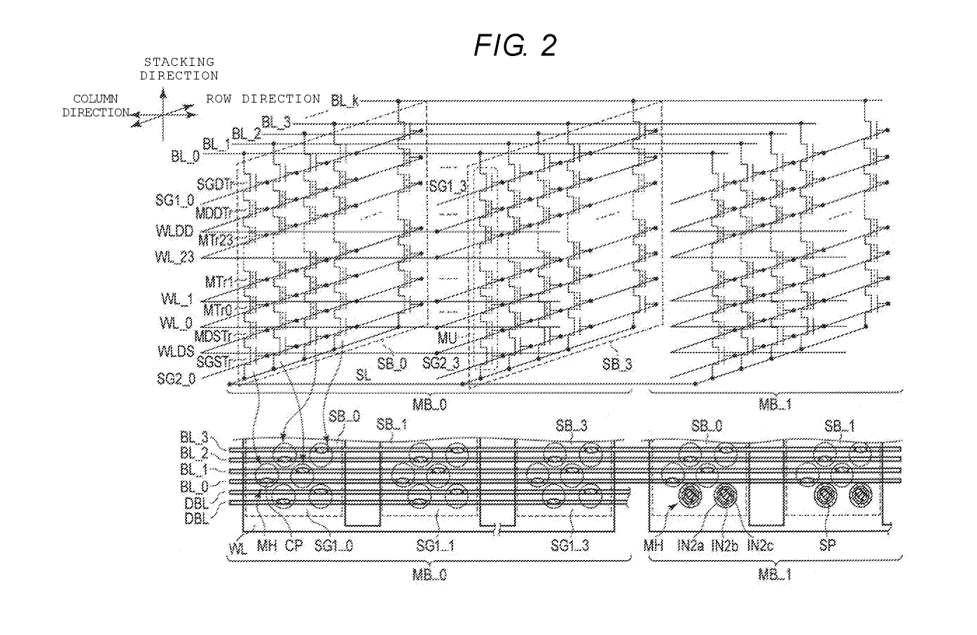

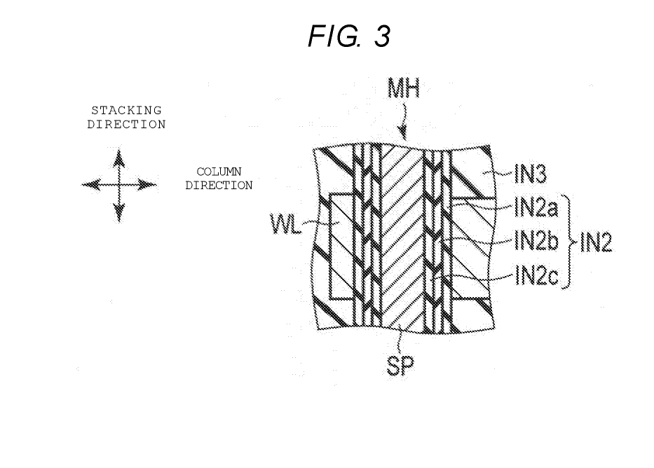

FIG. 2 is a perspective view of a part of the memory cell array according to the embodiment, and a view from above. FIG. 3 is a cross-sectional view illustrating one memory cell transistor. When reference names (for example, the word line WL, BL, and the like) with digits at the end are not needed to distinguished one from another, description in which the digits at the end are omitted is used and the description is intended to refer to all the reference names as if the digits are attached.

As illustrated in FIG. 2, the memory cell array 1 includes a plurality of blocks MB including a plurality of bit lines BL (BL_0 to BL_k), a common cell source line SL inside a cell array, and a plurality of sub-blocks SB.

Here, although four sub-blocks SB_0 to SB_3 are illustrated, of course, five or more sub-blocks may be used. Furthermore, although two blocks MB_0 and MB_1 are illustrated, of course, three or more blocks may be used.

The bit line BL extends in a column direction. The source line SL extends in the column direction. The source line SL is connected to a source line arranged within the sub-block. A plurality of word lines WL_0 to WL_23, dummy word lines WLDD and WLDS, and select gate lines SG1 and SG2 are stacked within each block MB in a direction (stacking direction) perpendicular to a row direction and a column direction. The word line WL, the dummy word lines WLDD and WLDS, and the select gate lines SG1 and SG2 extend in the row direction.

A memory unit MU includes a memory string, a source-side select gate transistor SGSTr, and a drain-side select gate transistor SGDTr. The memory string includes n+1 (for example, n is 23) memory cell transistors MTr0 to MTr23 which are connected in series and memory cell transistors MDDTr and MDSTr. A plurality of the memory units MU share the word line WL and the select gate lines SG1 and SG2, and form one unit. This unit is referred to as the sub-block SB.

A dummy cell transistor MDSTr is connected between the memory cell transistor MTr0 and the source-side select gate transistor SGSTr. A structure of the dummy cell transistor MDSTr is basically the same as that of the memory cell transistor, MTr, but the dummy cell transistor MDSTr is inserted to reduce the disturbance to the memory cell transistor or the select gate transistor during a write pulse applying operation or an erase pulse applying operation rather than for storing data. In this example, only one the dummy cell transistor MDSTr is inserted between the memory cell transistor MTr0 and the source-side select gate transistor SGSTr, but two or more dummy cell transistors may be inserted. Similarly, a dummy cell transistor MDDTr is connected between the memory cell transistor MTr23 and the drain-side select gate transistor SGDTr, and in the example, one is inserted, but two or more dummy cell transistors MDDTr may be inserted.

A drain of the select gate transistor SGSTr is connected to a source of the dummy cell transistor MDSTr, and a source of the select gate transistor SGSTr is connected to the source line SL. Furthermore, a source of the select gate transistor SGDTr is connected to a drain of the dummy cell transistor MDDTr, and a drain of the select gate transistor SGDTr is connected to the bit line BL.

A gate of each cell transistor MTr0 of a plurality of the memory units MU arranged along the row direction in each block MB is commonly connected to the word line WL_0. Similarly, each gate of each of the cell transistor MTr1 to MTr23 and each gate of the dummy cell transistors MDSTr and MDDTr of the plurality of the memory units MU arranged along the row direction in each block MB are respectively connected in common to the word line WL_1 to WL_23 and dummy word lines WLDS and WLDD.

As described above, the word lines WL are commonly connected in each block MB extending in the row direction. In addition, as depicted in the wire connections illustrated in FIG. 2 or depicted in a view of a lower portion of FIG. 2, in an end portion of the word line, adjacent word lines having the same height in a stacking direction are connected in the block MB. That is, as illustrated in FIG. 2, the sub-block SB includes the plurality of the memory units MU arranged in the row direction and the word lines WL having the same height in the stacking direction are commonly connected between at least two or more adjacent sub-blocks SB (sub-blocks SB_0 to SB_3 in the example). As described above, since a plurality of sub-blocks to which the word line WL is connected is, for example, simultaneously erased during the erase operation, such plurality of sub-blocks form the block MB.

As described above, when the word line is connected between the plurality of sub-blocks SB, the plurality of the memory units MU in which a potential of a selected word line is applied to one bit line are present. In order to prevent multiple selection, drain-side select gate lines SG1_0 to SG1_3 are provided separately for each sub-block at least on the drain side.

That is, a gate of each select gate transistor SGDTr of the plurality of the memory units MU arranged along the row direction in the sub-block SB_0 is commonly connected to the drain-side select gate line SG1_0. Hereinafter, similarly, SG1_1, SG1_2, and SG1_3 are respectively connected to the sub-blocks SB_1 to SB_3.

Furthermore, as illustrated in FIG. 3 described later, a semiconductor pillar SP is formed in a hole MH illustrated in FIG. 2. Two bit lines are arranged above the holes MH respectively. For example, the bit lines BL_0 and BL_1 are arranged above the hole MH. Furthermore, the bit line BL_0 is connected to a semiconductor pillar within the hole MH by a contact plug CP.

Furthermore, in the example, a separate source-side select gate line is provided in each sub-block. Agate of each select gate transistor SGSTr of the plurality of the memory units MU arranged along the row direction in the sub-block SB_0 is commonly connected to the source-side select gate line SG2_0. Hereinafter, similarly, SG2_1, SG2_2, and SG2_3 are respectively connected to the sub-blocks SB_1 to SB_3.

1.1.3 Configuration of Memory Cell Transistor

The memory cell transistor MTr has a structure illustrated in FIG. 3. As illustrated in FIG. 3, the hole MH is formed so as to pass through a plurality of the word line WL and an insulating film IN3 between the word lines, and the semiconductor pillar SP is arranged in the hole MH. For example, the word line (gate of the transistor MTr) WL is formed of polysilicon, polycide, or metal such as tungsten.

An insulating film IN2 is formed between the word line WL and the semiconductor pillar SP and between the insulating film IN3 and the semiconductor pillar SP. The insulating film IN2 includes a block insulating film IN2a, a charge storage film IN2b, and a tunnel insulating film IN2c.

The block insulating film IN2a is arranged between the word line WL and the charge storage film IN2b, and is, for example, formed of silicon oxide. The charge storage film IN2b is arranged between the block insulating film IN2a and the tunnel insulating film IN2c, is, for example, formed of silicon nitride (SiN), and stores charge. The tunnel insulating film IN2c is arranged between the charge storage film IN2b and the semiconductor pillar SP and, for example, is formed of silicon oxide (SiO2). Moreover, the semiconductor pillar SP is formed of a semiconductor (for example, silicon) into which a predetermined amount of impurity is introduced.

For example, a configuration of the memory cell array 1 is described in U.S. patent application Ser. No. 12/407,403 “Three Dimensional Stacked Nonvolatile Semiconductor Memory” filed on Mar. 19, 2009. The configuration is also described in U.S. patent application Ser. No. 12/406,524 “Three Dimensional Stacked Nonvolatile Semiconductor Memory” filed on Mar. 18, 2009; U.S. patent application Ser. No. 12/679,991 “Nonvolatile Semiconductor Storage Device and Method for Manufacturing Same” filed on Mar. 25, 2010; and U.S. patent application Ser. No. 12/532,030 “Semiconductor Memory and Method for Manufacturing Same” filed on Mar. 23, 2009. The entire contents of these patent applications are incorporated in this disclosure by reference.

1.1.4 Configuration of Row System Circuit

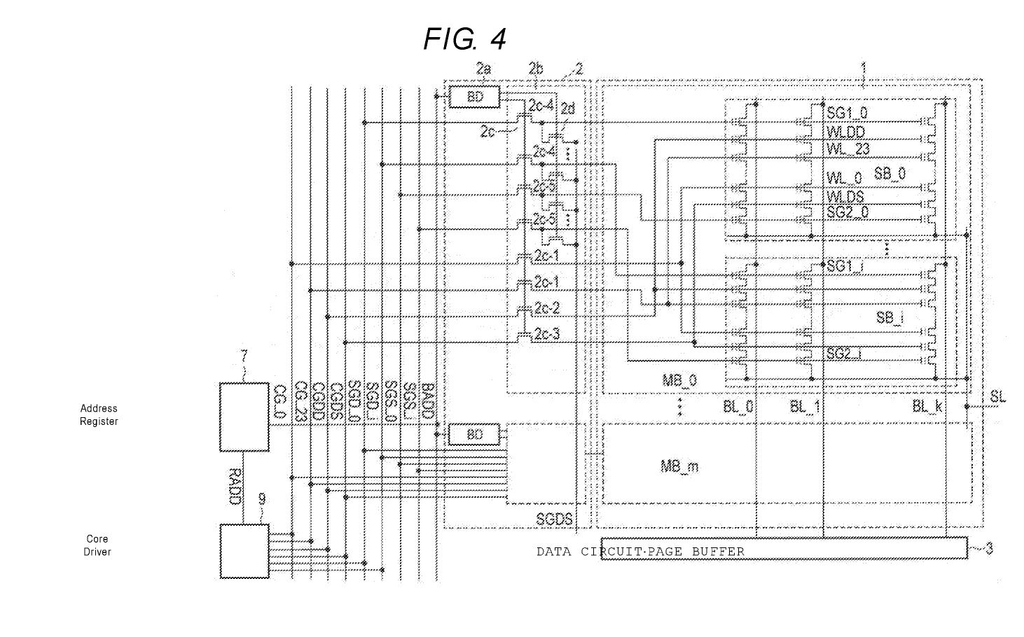

A connection relationship between the memory cell array, the row decoder, the data circuit•page buffer, and the core driver will be described with reference to FIG. 4.

The row decoder 2 includes a block decoder (BD) 2a and a transistor array 2b. A block address signal BADD is supplied from the address register 7 to the block decoder 2a. The block decoder 2a selects the block MB based on the block address signal BADD. The transistor array 2b includes transistors 2c and 2d.

The transistor 2c includes transistors 2c-1 to 2c-7. The transistor 2c-1 connects the word lines WL_0 to WL_23, and wirings CG_0 to CG_23, respectively. The transistor 2c_2 connects the dummy word line WLDD and wiring CGDD. The transistor 2c_3 connects the dummy word line WLDS and wiring CGDS. The transistor 2c_4 connects the select gate line SG1_0 to SG1_i and wirings SGD_0 to SGD_i, respectively. The transistor 2c_5 connects the select gate line SG2_0 to SG2_i and wirings SGS_0 to SGS_i, respectively. Symbol i indicates a natural number of 0 or more.

An appropriate voltage is applied from the core driver 9 to the wirings CG_0 to CG_23, CGDD, CGDS, SGD_0 to SGD_i, and SGS_0 to SGS_i during writing, reading, and erasing of data. Then, the voltage is transmitted to the word lines WL_0 to WL_23, the dummy word line WLDD and WLDS, and the select gate line SG1_0 to SG1_i, and SG2_0 to SG2_i, respectively by the transistor 2c within the row decoder 2.

1.2 Write Operation of Semiconductor Memory Device

Next, a write operation in the semiconductor memory device according to the embodiment will be described.

1.2.1 Summary of Write Operation

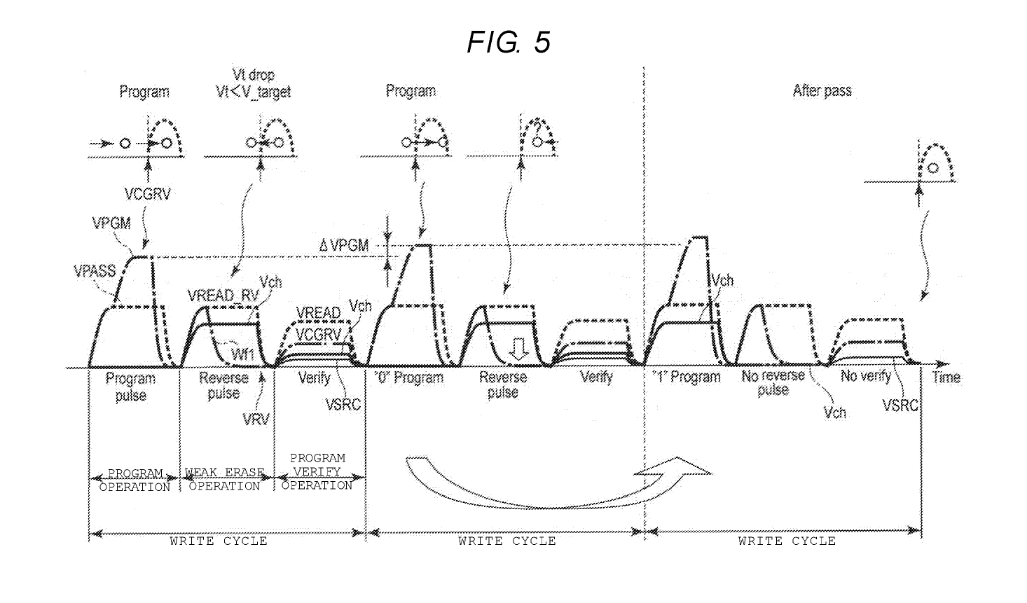

As illustrated in FIG. 5, in the write operation of the embodiment, a plurality of write cycles are repeatedly executed. Each write cycle includes three operations of a program operation, a weak erase operation, and a program verify operation. Here, a program raising a threshold of the memory cell transistor MTr is defined as “0” program and a program maintaining a threshold of the memory cell transistor MTr is defined as “1” program.

In the write operation, first, the control circuit 5 executes the write cycle with respect to the memory cell transistor and executes the write cycle again to perform the “0” program as a program operation with respect to the memory cell transistor that does not pass the program verify operation. On the other hand, the control circuit 5 executes the “1” program as the program operation with respect to the memory cell transistor that passes the program verify operation and executes the program verify operation without applying a reverse stress (described in detail later) in the weak erase operation.

Hereinafter, the program operation, the weak erase operation, and the program verify operation will be described. The operations are, for example, executed by a command of the control circuit 5. That is, the voltage generating circuit 8 generates various voltages and the core driver 9, the row decoder 2, and the data circuit•page buffer 3 (sense amplifier 3a) transmits the voltages supplied from the voltage generating circuit 8 to the word line or the bit line at a predetermined timing according to the command of the control circuit 5.

First, the program operation will be described. The row decoder 2 in the program operation allows the drain-side select gate transistor SGDTr to be in an ON state by transmitting, for example, a positive voltage to the select gate line SG1. Furthermore, the row decoder 2 allows the source-side select gate transistor SGSTr to be in an OFF state by transmitting, for example, 0 V to the select gate line SG2.

Next, the sense amplifier 3a applies a voltage VBLL (for example, 0 V) to the channel of the memory cell transistor through the bit line for the memory cell transistor executing the “0” program. On the other hand, the sense amplifier 3a applies a voltage VBLH (for example, 2.5 V) to the bit line for the memory cell transistor executing the “1” program. The voltage VBLH allows the select gate transistor to be cut off when the positive voltage is applied to the gate of the select gate transistor.

Thereafter, the row decoder 2 transmits a program voltage VPGM (for example, 20 V) to a selected word line and a voltage VPASS (for example, 10 V) to a non-selected word line. The voltage VPGM injects electrons of the channel to a charge storage layer by tunneling. The voltage VPASS allows the memory cell transistor MTr to be in the ON state regardless of data held, a potential of the channel to be increased by coupling, and injection of the electrons to the charge storage layer to be suppressed.

Thus, electrons of one of the memory cell transistors MTr connected to the selected word line WL, which corresponds to a column where the voltage VBLL is applied to the bit line BL, are injected into the charge storage layer, and the “0” program is executed. That is, a threshold level of the memory cell transistor MTr is increased. On the other hand, the memory cell transistor MTr corresponding to the column where the voltage VBLH is applied to the bit line BL is in the ON state, the channel is formed, and the channel is in an electrically floating state. Thus, since a potential Vch of the channel is boosted substantially to VPASS, electrons are not injected into the memory cell transistor and the “1” program is executed. That is, the threshold level of the memory cell transistor MTr is maintained.

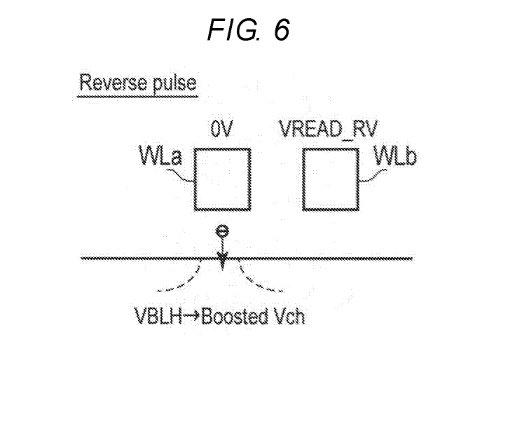

Next, the weak erase operation will be described. In the weak erase operation, the row decoder 2 allows the drain-side select gate transistor SGDTr to be in the ON state by transmitting, for example, the positive voltage to the select gate line SG1. Furthermore, the row decoder 2 allows the source-side select gate transistor SGSTr to be in the OFF state by transmitting, for example, 0 V to the select gate line SG2. Next, as illustrated in FIG. 6, the sense amplifier 3a applies the voltage VBLH (for example, 2.5 V) to the channel of the memory cell transistor MTr through the bit line.

Here, the row decoder 2 transmits 0 V to the selected word line and a voltage VREAD_RV (for example, 10 V) to the non-selected word line. The voltage VREAD_RV allows the memory cell transistor MTr to be in the ON state regardless of held data and generates the reverse stress (may be referred to as the reverse pulse) by increasing the potential of the channel by coupling. The voltage VREAD_RV is applied to the non-selected word line, whereby the memory cell transistor MTr connected to the non-selected word line is in the ON state. On the other hand, 0 V is applied to the selected word line, whereby the memory cell transistor MTr connected to the selected word line is in the OFF state.

Then, since the drain-side select gate transistor SGDTr and the source-side select gate transistor SGSTr are in the OFF state, the channel formed within the memory unit MU is in the electrically floating state. Thus, the potential of the channel is boosted by the voltage VREAD_RV of the non-selected word line and increases to the voltage Vch (substantially VREAD_RV). As a result, the voltage of the selected word line is 0 V and the potential of the channel is the voltage Vch, and thus a large potential difference, that is, stress is applied to the memory cell transistor MTr. This is “the reverse stress” as referred to in this disclosure. That is, the reverse stress is a voltage stress similar to the erase operation of data which is applied to the memory cell transistor MTr connected to the selected word line. The voltage VREAD_RV is a voltage applied to the non-selected word line in the weak erase operation and is a voltage for boosting the potential of the channel of the memory cell transistor MTr. Moreover, further detailed operation of the weak erase operation will be described later.

Following the weak erase operation, the program verify operation is performed. The program verify operation is an operation determining whether or not the threshold voltage of the selected memory cell transistor reaches a target threshold level. Details of the program verify operation will be described later.

When the memory cell transistor fails the program verify operation, the control circuit 5 performs the write cycle again. That is, the program operation, the weak erase operation, and the program verify operation are performed again. In this case, the program voltage VPGM in the program operation is set to be higher than the program voltage VPGM of previous write cycle by ΔVPGM. Then, the write cycle is repeated until the memory cell transistor passes the program verify operation.

Moreover, the control circuit 5 may terminate the write operation when the number of the memory cells that failed the program verify operation is less than a certain number. Furthermore, the control circuit 5 may terminate the write operation as a defective write operation when the number of the write cycles reaches the maximum value.

1.2.2 Details of Weak Erase Operation and Program Verify Operation

Next, details of the weak erase operation and the program verify operation will be described. Here, as examples of the weak erase operation and the program verify operation, three examples of first to third examples are illustrated.

1.2.2.1 Weak Erase Operation and Program Verify Operation of First Example

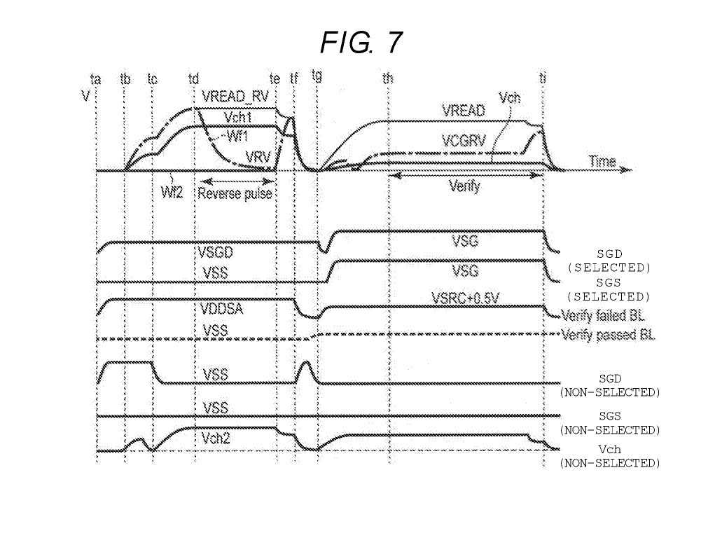

FIG. 7 illustrates voltage waveforms of the weak erase operation and the program verify operation of the first example. In the first example, each operation is started after charge and discharge of the word line WL are performed in each of the weak erase operation and the program verify operation subsequent to the weak erase operation.

First, the weak erase operation (time ta to time tg) will be described. In FIG. 7, a waveform of the selected word line is indicated by Wf1.

The row decoder 2 transmits a voltage VSGD (here, the voltage is the same as the voltage VSGD applied to the program operation, but also may use the voltage VSGD_RV that is optimized to the weak erase operation) to the gate of the drain-side select gate transistor SGDTr between the time ta and the time tg. Furthermore, the row decoder 2 transmits a voltage VSS to the gate of the source-side select gate transistor SGSTr. Here, since the threshold voltage of each select gate transistor is appropriately 1 V to 2 V, when VSGD=2.5 V is satisfied, the drain-side select gate transistor SGDTr is in a conductive state by a voltage level of a source terminal (terminal on a side connecting to the memory cell) thereof and the source-side select gate transistor SGSTr is in the OFF state.

Furthermore, the sense amplifier 3a applies a voltage VDDSA (for example, 2.5 V) to the bit line corresponding to the memory cell transistor MTr that does not pass the program verify operation between the time ta and the time tf. When the bit line is charged to the voltage VDDSA from the time ta, when the source terminal of the drain-side select gate transistor SGDTr increases to “VSGD-Vt_SGD” (Vt_SGD is a threshold voltage of the drain-side select gate transistor), the drain-side select gate transistor is in a cut-off state.

Next, the row decoder 2 allows voltages of the selected word line and the non-selected word line to increase to the voltage VREAD_RV between the time tb and the time td. In this case, since the select gate transistor SGDTr is in the cut-off state, the channel is in a floating state. Thus, the channel of the memory cell transistor MTr is boosted by coupling with the voltage VREAD_RV of the word line WL and the potential thereof increases to a potential Vch1 (≈VREAD_RV).

Furthermore, after the time td, the row decoder 2 continuously applies the voltage VREAD_RV to the non-selected word line WL and decreases the potential of the selected word line WL from the voltage VREAD_RV to a voltage VRV (for example, the voltage VSS=0 V). As a result, a potential of a control gate of the selected memory cell transistor is, for example, 0 V, the channel region of the selected memory cell transistor has the potential Vch1 that is boosted by the non-selected memory cell transistor, and a large potential difference is generated between both potentials. Thus, it is possible to apply the reverse stress to the selected memory cell transistor.

Thereafter, application of the reverse stress is terminated and the potential of the word line is decreased in a period between the time to and the time tg. As an example, FIG. 7 illustrates waveforms in which potentials of the selected word line and the non-selected word line are discharged after being equalized. When the core driver 9 that drives the selected word line and the non-selected word line, the selected word line, and the non-selected word line are shut off, and the selected word line and the non-selected word line are floated, the potential of the selected word line is increased by capacitive coupling between the selected word line and the non-selected word line, and the potential of the non-selected word line is slightly decreased between the time to and the time tf. Thereafter, at the time tf, the potentials of the selected word line and the non-selected word line are discharged by the core driver 9.

When the voltage of the word line WL is discharged and the operation is terminated, in a case that there is a large potential difference between the word lines inside the sub-block, there are cases that may cause some kinds of disturbance to occur and it is undesirable. Thus, as described above, the potentials of the selected word line and the non-selected word line are equalized and the potential difference between the word lines is eliminated before the potential of the word line is discharged.

The memory cell transistor MTr that passes the program verify operation is not subject to the reverse stress by the weak erase operation. Thus, the sense amplifier 3a applies the voltage VSS with respect to the bit line BL corresponding to the memory cell transistor MTr that is not subject to the reverse stress by the weak erase operation between the time to and the time tf. In this case, the select gate transistor SGDTr is turned ON, the channel of the memory unit MU including the memory cell transistor MTr is not in the floating state and the potential of the channel is not boosted by the voltage VREAD_RV of the non-selected word line, and the voltage VSS is maintained. Thus, since the potential difference between the gate of the memory cell transistor MTr and the potential of the channel within the memory unit MU is substantially 0 V, the reverse stress is not applied to the memory cell transistor MTr that passes the program verify operation.

Next, the program verify operation (the time tg to the time ti) that is performed after the weak erase operation described above will be described.

The row decoder 2 transmits verify voltage VCGRV to the selected word line and transmits a voltage VREAD to the non-selected word line between the time tg and the time th. The voltage VREAD is a voltage allowing the non-selected memory cell transistor to be in the ON state to pass a cell current. Thus, the memory cell transistor connected to the non-selected word line to which the voltage VREAD is applied is in the ON state regardless of the held data. The voltage VCGRV corresponds to the threshold level that is a target corresponding to the write data of the memory cell transistor MTr and is used to determine whether or not the threshold of the memory cell transistor reaches the threshold level of the target in the program verify operation.

The row decoder 2 transmits a voltage VSG to the gate between the drain-side select gate transistor SGDTr and the source-side select gate transistor SGSTr within the selected sub-block between the time th and the time ti. Thus, the select gate transistors SGDTr and SGSTr are in the ON state.

Here, a source line driver (not illustrated) allows a potential of a source line CELSRC (SL) to be a voltage VSRC and the sense amplifier 3a allows the potential of the bit line to be a voltage higher than the voltage VSRC by, for example, appropriately 0.5 V. Furthermore, the row decoder 2 applies the voltage VCGRV to the selected word line WL and applies the voltage VREAD to the non-selected word line. Thus, in the selected sub-block, when the threshold of the memory cell transistor MTr is the verify voltage VCGRV or less, the memory cell transistor is turned ON and the cell current flows from the bit line to the source line. On the other hand, when the threshold of the memory cell transistor is higher than the verify voltage VCGRV, the memory cell transistor is not turned ON and the cell current does not flow from the bit line to the source line.

The sense amplifier 3a detects whether or not the threshold of the memory cell transistor of the write target reaches the threshold level that is a target corresponding to the write data by detecting the cell current described above. When the sense amplifier 3a detects that the threshold of the memory cell transistor reaches the threshold level of the target, the control circuit 5 determines that the memory cell transistor passes the program verify operation, the “1” program is executed in the program operation of the next write cycle, the reverse stress is not applied in the weak erase operation, and the program verify operation is also not executed. On the other hand, when the sense amplifier 3a does not detect that the threshold of the memory cell transistor reaches the threshold level of the target, the control circuit 5 determines that the memory cell transistor does not pass the program verify operation and executes the write cycle again.

Furthermore, in the non-selected sub-block, in an initial stage of the weak erase operation, the row decoder 2 transmits the voltage VSG to the gate of the drain-side select gate transistor SGDTr and then transmits the voltage VSS. Furthermore, the row decoder 2 transmits the voltage VSS to the gate of the source-side select gate transistor SGSTr and then transmits the voltage VSS. Thus, the potential of the channel of the memory cell transistor within the non-selected sub-block increases to a voltage Vch2. However, since the voltage Vch2 of the channel within the non-selected sub-block may be controlled, excess stress is not applied to the memory cell transistor MTr. The voltage VSG allows the select gate transistor to be sufficiently in the ON state regardless of the potential of the select gate transistor on the source side.

In the first example described above, in the weak erase operation, the row decoder 2 allows the potential of the selected word line to increase to the voltage VREAD_RV before decreasing to the voltage VRV between the time tb and the time td similar to the non-selected word line. As described above, when the potential of the selected word line is increased to the voltage VREAD_RV before decreasing to the voltage VRV, the channels of all memory cell transistors MTr within the sub-block are simultaneously increased. Thereafter, it is possible to apply the reverse stress to the memory cell transistor by decreasing the voltage of the selected word line from an entirely high state of the potential of the channel without giving rise to the potential difference that generates some disturbance to the drain side and the source side of the selected memory cell transistor. Moreover, the voltage of the selected word line may be the voltage VRV (in this example, the voltage VRV=0 V) from the time tb as indicated by a waveform Wf2 illustrated in FIG. 7.

In the weak erase operation of the first example, after the selected word line becomes the voltage VRV, potential of the selected word line increases to the same potential as that of the non-selected word line, and then is discharged to the voltage VSS. Thus, it is possible to set the boost of the channel during the weak erase operation without limiting it to the verify voltage during the program verify operation. For example, it is possible to apply a boost method of the channel in the program operation that is previously executed. In the boost of the channel during the program operation, the voltage applied to the word line is optimized such that an execution state of the “1” program has uniformly good characteristics wherever the selected word line is positioned within the sub-block. That is, it is possible to obtain a stable potential of the channel and as a result, it is possible to apply a stable reverse stress to the memory cell according to an applying method of a program pulse to the word line during the program operation.

1.2.2.2 Weak Erase Operation and Program Verify Operation of Second Example

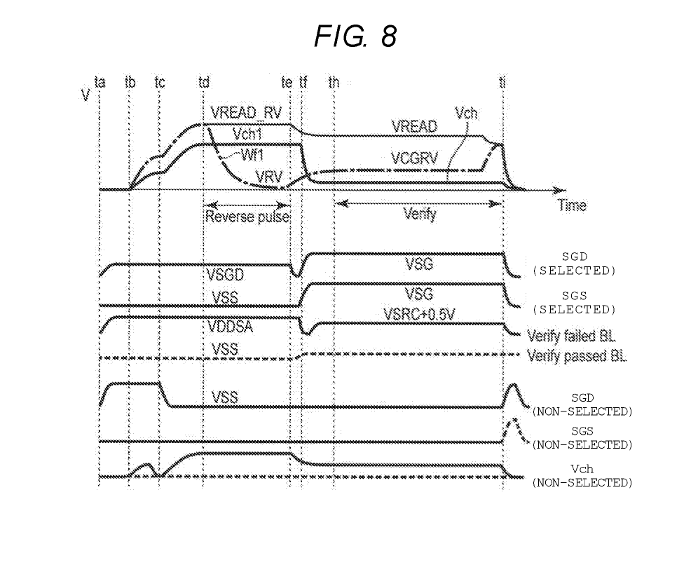

FIG. 8 illustrates voltage waveforms of a weak erase operation and a program verify operation of the second example. The second example substantially corresponds to the first example in FIG. 7 in which the operations of the period of the time te to the time tg are omitted. That is, in the second example, after the reverse stress is applied, the voltage VRV (for example, 0 V) applied to the selected word line is allowed to transition directly to the verify voltage VCGRV and the voltage VREAD_RV applied to the non-selected word line is allowed to transition directly to the voltage VREAD of the non-selected word line when verifying.

As indicated between the time te and the time th, the row decoder 2 transitions the voltage VRV applied to the selected word line to the verify voltage VCGRV and transitions the voltage VREAD_RV applied to the non-selected word line to the voltage VREAD of the non-selected word line during the verify operation without decreasing the voltage VREAD_RV to the voltage VSS after applying the reverse stress. The other basic operation waveforms are similar to those of the first example illustrated in FIG. 7.

In the second example illustrated in FIG. 8, the selected word line, the non-selected word line, and the channel are not discharged to the voltage VSS and the weak erase operation and the program verify operation are continuously performed between application of the reverse stress and the program verify operation. Thus, it is possible to expect that the working hour in which a time that is required for the write operation, may be shortened.

1.2.2.3 Weak Erase Operation and Program Verify Operation of Third Example

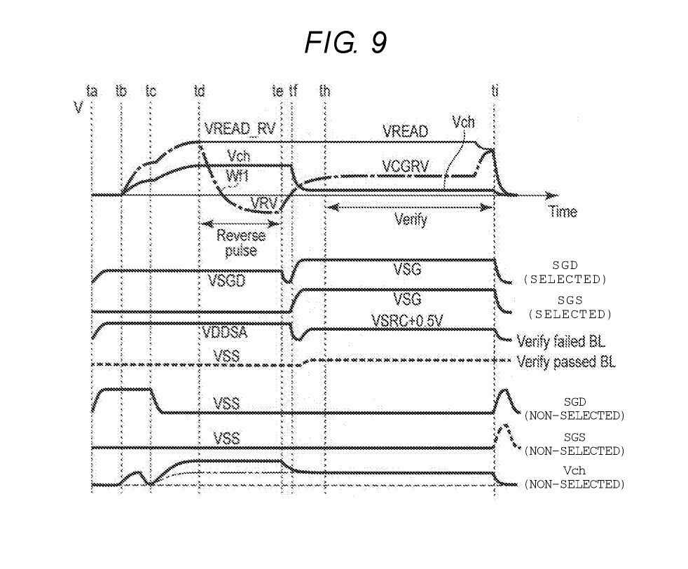

FIG. 9 illustrates voltage waveforms of a weak erase operation and a program verify operation of the third example. The third example is an example in which the row decoder 2 applies a voltage (negative voltage) lower than the voltage VSS as the voltage VRV or a voltage lower than the voltage of the source line to the selected word line in the first example or the second example of the weak erase operation described above. The other basic operation waveforms are similar to those of the first and second examples.

In the third example illustrated in FIG. 9, since the voltage VRV of the selected word line is set as the negative voltage during application of the reverse stress, it is possible to apply the reverse stress using the potential Vch of the channel that is lower than the potential Vch1 of the channel that is required to be applied when the voltage VRV is the voltage VSS. Thus, the voltage VREAD_RV applied to the non-selected word line may be lower than a case where the voltage VRV is the voltage VSS, and it is possible to match the voltage VREAD_RV to the voltage VREAD during write verifying.

1.3 Effect of this Embodiment

According to the embodiment, the reverse stress is applied to the memory cell transistor that fails the program verify operation and the reverse stress is not applied to the memory cell transistor that passes the program verify operation. Thus, it is possible to suppress a decrease in the threshold voltage of the memory cell after writing by not applying the voltage stress that is not required in the write operation.

The effect will be described in detail with reference to a comparison example.

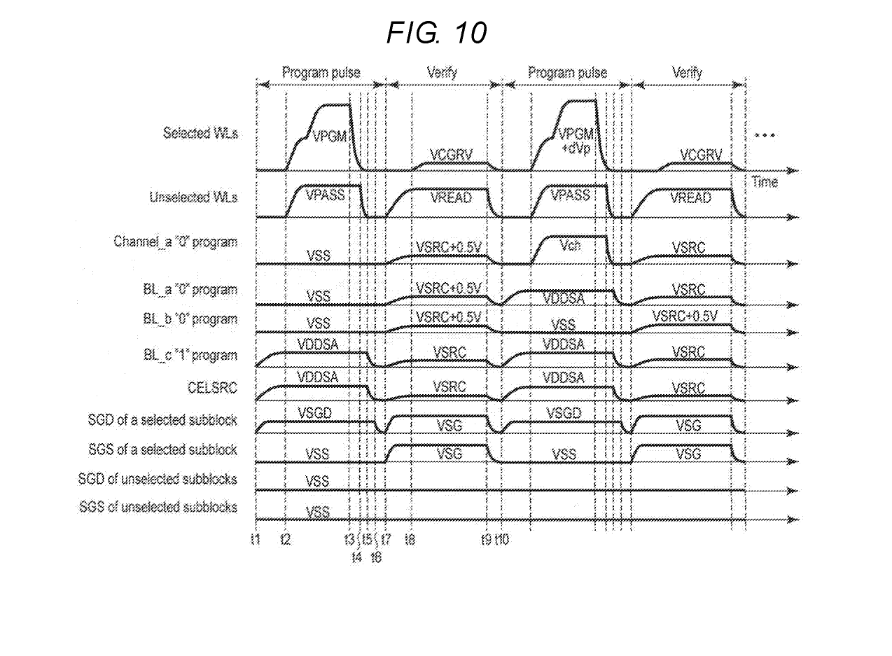

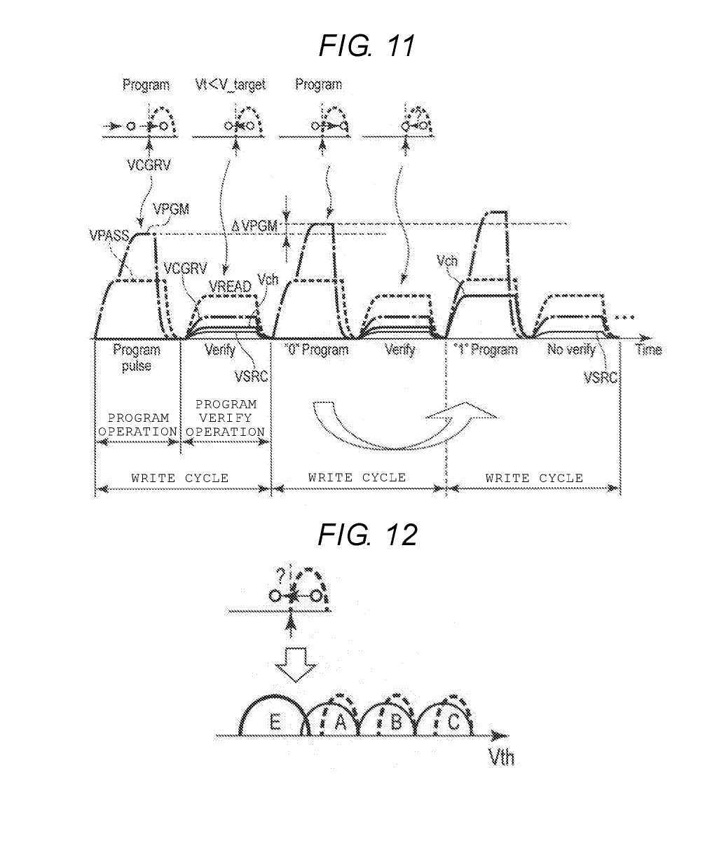

First, in a write operation of the comparison example, as illustrated in FIGS. 10 and 11, the write operation is performed by repetition of the write cycle including the program operation and the program verify operation. As illustrated in FIG. 11, in the program operation, the voltage VPGM is applied to the selected word line WL and the voltage VPASS is applied to the non-selected word line WL. Furthermore, in the program verify operation, the voltage VCGRV is applied to the selected word line and the voltage VREAD is applied to the non-selected word line. Furthermore, the potentials of the bit line BL and the channel are set as the voltage Vch and the potential of the source line CELSRC is set as the voltage VSRC, respectively.

In such a write operation, when performing program verify, in a case where it is determined that the threshold of the memory cell transistor exceeds the verify voltage VCGRV, in the write cycle thereafter, such a write operation is removed from the target of the program operation and the program verify operation (lockout). Thus, thereafter, when the threshold of the memory cell that is locked out due to fast de-trapping of electrons that are trapped in the charge storage layer decreases, as illustrated in FIG. 12, a threshold distribution after writing is spread on a low threshold side and a read margin may not be sufficiently secured.

In contrast, in the embodiment, the reverse stress is applied to a memory cell transistor as needed. Thus, it is possible to suppress the decrease in the threshold of the memory cell transistor after writing by not applying the voltage stress where it is unnecessary to the memory cell transistor in the write operation. In other words, the reverse stress is applied only to the memory cell transistor that fails and the threshold of the memory cell transistor that passes the program verify operation is not decreased by controlling the voltage applied to each bit line, that is, by applying the reverse stress due to the weak erase operation only to the memory cell transistor that fails the program verify operation and by performing control in which the reverse stress is not applied to the memory cell transistor that passes the program verify operation.

Furthermore, in the write operation according to the embodiment, after the program operation and before the program verify operation, the weak erase operation in which a potential difference in a direction of weak erase is applied to the memory cell transistor, is performed. As a result, it is possible to decrease a threshold of an unstable memory cell transistor at that point. When the memory cell transistor fails in the program verify operation, it is possible to perform re-writing in the memory cell by the next program operation. In the program verify operation, the memory cell transistor that is resistant to the stress in the direction of the weak erase passes and thereafter, it is locked out. Thus, after the write operation, it is possible to perform the write operation in which the decrease in the threshold distribution due to fast de-trapping is unlikely to occur. That is, the memory cell transistor in which the threshold may be decreased is found out in the write operation due to fast de-trapping and such a memory cell transistor is firmly written to a desired verify level. Thus, it is possible to sufficiently secure the read margin.

Furthermore, the weak erase operation, that is, an operation for applying a weak erase voltage is included in a write operation sequence, whereby it is possible to reduce an influence of the decrease in the threshold due to fast de-trapping in a nonvolatile memory cell having, for example, a MONOS/SONOS type film configuration.

### 2. Second Embodiment

Next, a semiconductor memory device according to a second embodiment will be described. In the semiconductor memory device described in the first embodiment described above, this embodiment relates to a control of the non-selected sub-block. Hereinafter, only the features different from those of the first embodiment will be described.

2.1 Summary of Weak Erase Operation According to this Embodiment

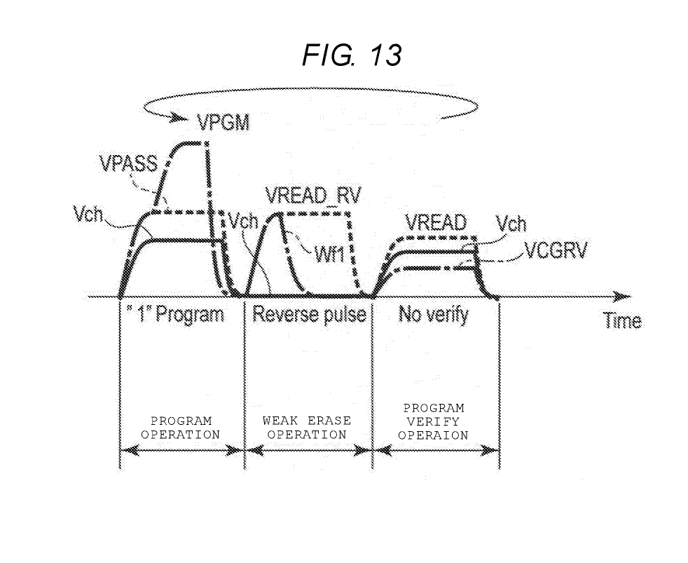

FIG. 13 illustrates a change over time of the voltages of the word line and the potential of the channel within the non-selected sub-block during the write operation of the second embodiment.

As illustrated in FIG. 13, in the weak erase operation, the potential Vch of the channel of the memory cell transistor within the non-selected sub-block is maintained in the voltage VSS (for example, 0 V). Thus, the reverse stress is not applied to the non-selected memory cell.

2.2 Specific Example of Weak Erase Operation According to this Embodiment

2.2.1 Weak Erase Operation According to First Example

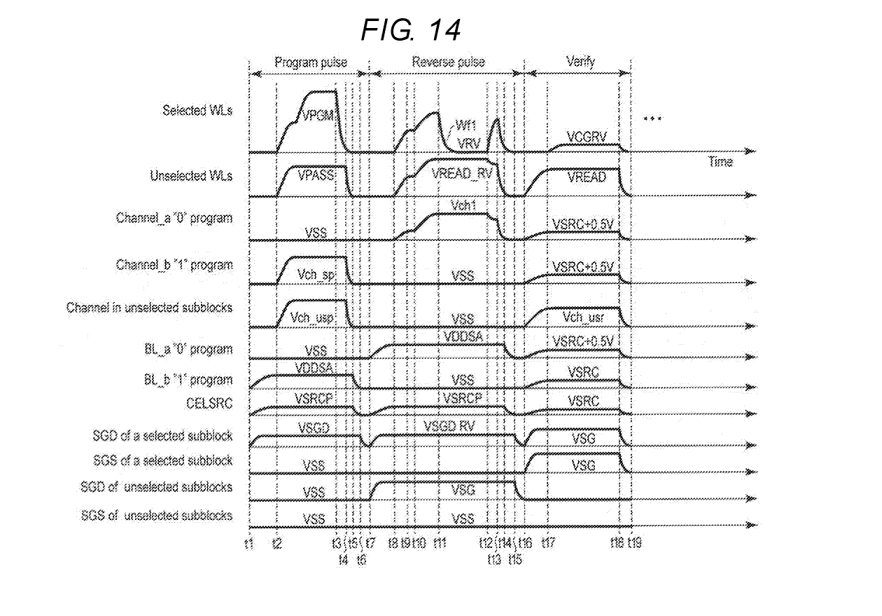

FIG. 14 illustrates the voltage waveforms of the weak erase operation according to the first example. Here, the weak erase operation is described. Since the program operation and the write verify operation are similar to those of the first embodiment, the description will be omitted.

As illustrated in the time t7 to the time t16, the weak erase operation is executed as follows.

In the time t7, first, application of a select gate voltage and application of a bit line voltage are started. As illustrated in the time t11 to the time t12, the row decoder 2 transmits the voltage VRV to the selected word line and transmits the voltage VREAD_RV to the non-selected word line. Thus, the reverse stress is applied to the memory cell transistor. The voltage waveform of the selected word line is indicated by wf1 as described above. The row decoder 2 allows the voltage of the selected word line and the voltage of the non-selected word line to be the same potential, and increases both together from time t8 to time t11. Thus, the potential of the channel is boosted. Thereafter, the row decoder 2 allows the potential of the selected word line to be lowered to the voltage VRV (in this case, 0 V) and the voltage VREAD_RV is kept constant from time t11 to time t12. This is the same as the description in the first embodiment.

In the non-selected sub-block, the row decoder 2 transmits the voltage VSG to the gate of the drain-side select gate transistor SGDTr and transmits the voltage VSS to the gate of the source-side select gate transistor SGSTr between time t8 and time t15. The voltage VSG allows the select gate transistor SGDTr to be sufficiently in the ON state regardless of the potential on the source side of the select gate transistor SGDTr.

As a result, in the non-selected sub-block, since the select gate transistor SGDTr is turned ON, the potential of the channel within the non-selected sub-block is maintained in the same voltage as the voltage of the bit line. For example, when the voltage of the bit line is the voltage VDDSA, the potential of the channel is the voltage VDDSA of the bit line. Furthermore, when the voltage of the bit line is the voltage VSS, the potential of the channel is the voltage VSS of the bit line. Furthermore, since the select gate transistor SGDTr remains in the ON state, the channel within the non-selected sub-block is not in the floating state, the potential of the channel is not boosted by the voltage VREAD_RV of the non-selected word line, and is maintained at the voltage VDDSA or the voltage VSS. Thus, the reverse stress is not applied to the memory cell transistor within the non-selected sub-block.

2.2.2 Weak Erase Operation According to Second Example

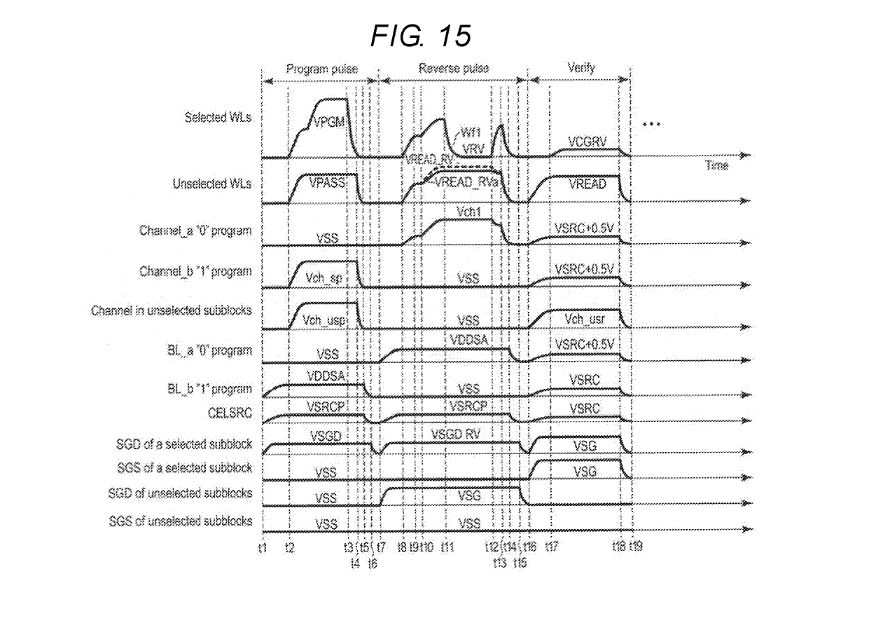

FIG. 15 illustrates voltage waveforms of the weak erase operation according to the second example. The second example is a modification example of the first example. The second example is an example in which the voltage of at least one non-selected word line adjacent to the selected word line is set as a voltage VREAD_RVa different from the voltage VREAD_RV. For example, the voltage VREAD_RVa is set as a voltage slightly lower than the voltage VREAD_RV. Since the other voltage waveforms are the same as those of the first example illustrated in FIG. 14, the description will be omitted.

2.3 Effect According to this Embodiment

In the embodiment described above, since potential of the channel of the memory cell transistor within the non-selected sub-block may be maintained substantially at voltage VSS, the reverse stress is not applied to the memory cell transistor within the non-selected sub-block. As a result, it is possible to reduce the applied reverse stress.

Furthermore, in the second example illustrated in FIG. 15, the potential difference between the selected word line and the non-selected word line adjacent thereto may be adjusted and optimized when applying the reverse stress in the weak erase operation. The goal of the reverse stress is to apply a weak erase stress in a direction opposite to the program pulse between the gate of the memory cell transistor and the channel. However, when the voltage VREAD_RV that is relatively high is required, the potential difference between the word lines becomes large, and a large potential difference is temporarily generated between the regions of the channel of the memory cell transistor, such that tunneling between bands occurs, and there is a possibility that an injection phenomenon of superfluous carriers occur. Thus, the voltage of the non-selected word line adjacent to the selected word line is the voltage VREAD_RVa (VREAD_RVa<VREAD_RV), which is capable of being adjusted, whereby it is possible to apply the reverse stress to the selected memory cell transistor while not applying the potential difference that is locally large between adjacent memory cells.

### 3. Third Embodiment

Next, a semiconductor memory device according to a third embodiment will be described. In the embodiment, the non-selected sub-block is controlled by a method different from that of the second embodiment described above. Hereinafter, only the features different from those of the first embodiment and the second embodiment will be described.

3.1 Summary of Weak Erase Operation According to this Embodiment

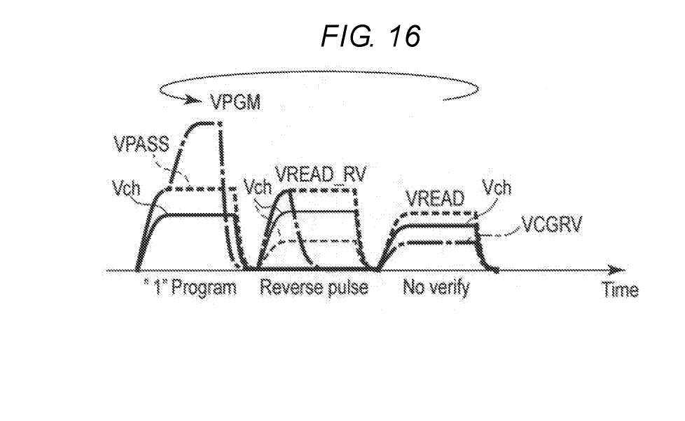

FIG. 16 illustrates change over time of the potentials of the word line and the channel within the non-selected sub-block during a write operation according to the third embodiment.

In the weak erase operation, when the select gate transistor SGDTr within the non-selected sub-block is in an OFF state, otherwise, when the select gate transistor SGDTr is in an ON state at an initial stage of the weak erase operation and then is in the OFF state, the potential Vch of the channel of the memory cell transistor within the non-selected sub-block is boosted, and as illustrated in FIG. 16, is increased respectively. In the third embodiment, the potential Vch of the channel is controlled such that the increase in the potential Vch is not too high. Thus, the reverse stress to be applied to the selected memory cell transistor is not applied strongly and the reverse stress is applied to the memory cell transistor within the non-selected sub-block is applied weakly.

3.2 Specific Example of Weak Erase Operation According to this Embodiment

3.2.1 Weak Erase Operation According to First Example

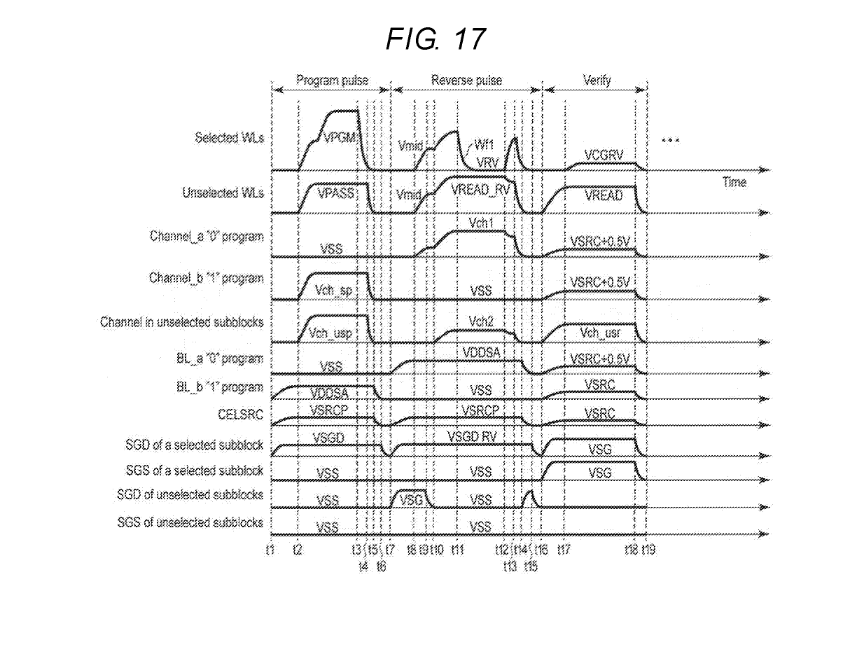

FIG. 17 illustrates voltage waveforms of the weak erase operation according to the first example. Here, similar to the second embodiment, the weak erase operation is described. Since the program operation and the write verify operation are similar to those in the first embodiment, the description will be omitted.

The weak erase operation illustrated in FIG. 17 is an example in which the select gate transistor SGDTr within the non-selected sub-block is in an ON state immediately before the reverse stress is applied and immediately after the reverse stress is applied.

As illustrated in time t7 to time t16, the weak erase operation is operated as follows.

The row decoder 2 transmits the voltage VSG to the gate of the drain-side select gate transistor SGDTr between the time t7 and the time t9, and transmits the voltage VSS to the gate of the select gate transistor SGDTr between the time t10 and the time t14. Furthermore, the row decoder 2 transmits the voltage VSS to the gate of the source-side select gate transistor SGSTr.

When the voltage of the bit line is the voltage VDDSA between the time t7 and the time t9, the select gate transistor SGDTr is turned ON by the voltage VSG applied to the gate. Here, the row decoder 2 transmits a voltage Vmid to the word line in the time t8. In such a case, when the voltage VSG applied to the gate of the drain-side select gate transistor does not cause the voltage VDDSA applied to the bit line to conduct, the potential of the channel is increased by coupling with the word line to which the voltage Vmid is applied. However, since the voltage is set such that the select gate transistor maintains the conductive state, the potential of the channel is not increased.

Thereafter, the row decoder 2 transmits the voltage VSS to the gate of the select gate transistor SGDTr in the time t10 or later. Thus, the select gate transistor SGDTr is in the OFF state. Thus, the channel within the non-selected sub-block is in the floating state, and the potential of the channel is increased by a potential difference between the voltage VREAD_RV applied to the word line and the voltage Vmid, and becomes the voltage Vch2. Thus, the voltage Vch2 of the channel is indicated by a relational expression: initial voltage (VDDSA or 0 V) of period between the time t7 and the time t9+coupling ratio×(VREAD_RV−Vmid). That is, when the voltage Vmid is set to be high, it is possible to set the potential Vch2 to be low. The potential of the channel may be set to be lower than the potential Vch1 of the channel when the reverse stress is applied. Thus, control may be performed such that the reverse stress is not applied to the memory cell within the non-selected sub-block.

On the other hand, when the sense amplifier 3a applies the voltage VSS to the bit line between the time t7 and the time t9, since the select gate transistor SGDTr is turned ON, the channel within the non-selected sub-block is the voltage VSS of the bit line. Thereafter, when the voltage of the gate of the select gate transistor SGDTr in the time t10 or later is the voltage VSS, the select gate transistor SGDTr is in the OFF state. Thus, the channel within the non-selected sub-block is in the floating state and the potential of the channel is boosted by the potential difference between the voltage VREAD_RV applied to the word line and the voltage Vmid, and the voltage of the bit line is increased to the potential Vch2 of the channel that is lower than a case of the voltage VDDSA. Thus, in this case, it becomes the reverse stress that is weaker than a case where the voltage VDDSA is applied to the bit line.

3.2.2 Weak Erase Operation According to Second Example

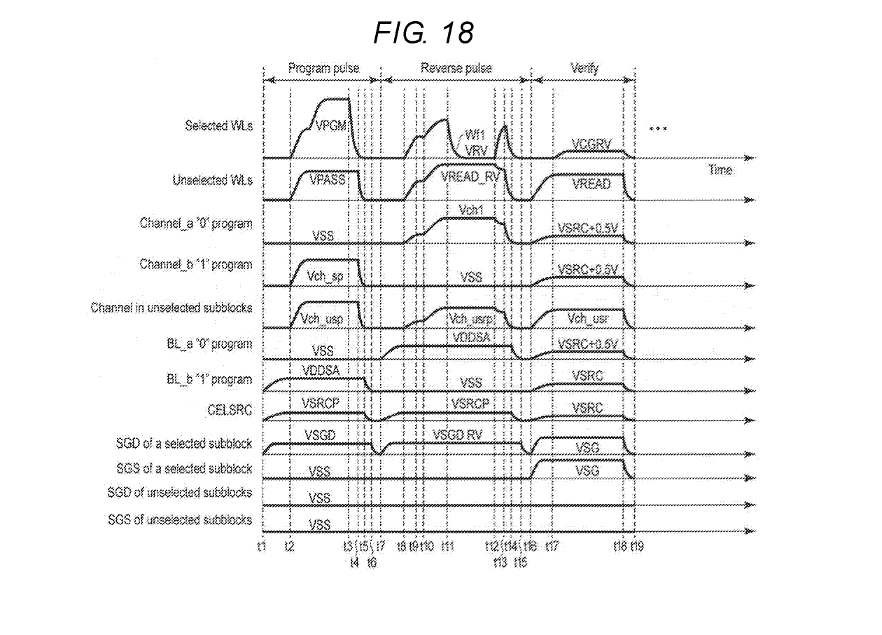

FIG. 18 illustrates voltage waveforms of the weak erase operation according to the second example. In the second example, the select gate transistor SGDTr within the non-selected sub-block is in an OFF state in a period of the weak erase operation. Since operations except the following description are the same as those of the second embodiment, the description of the operations will be omitted.

As illustrated in time t7 to time t16, the weak erase operation is operated as follows.

The row decoder 2 transmits the voltage VSS to the gates of the drain-side select gate transistor SGDTr and the source-side select gate transistor SGSTr between the time t7 and the time t16. Thus, the select gate transistors SGDTr and SGSTr are in the OFF state together.

Here, as described above, the select gate transistor SGDTr is in the OFF state during an operation period in which the reverse stress is applied. Furthermore, the row decoder 2 transmits the voltage VRV to the selected word line and the voltage VREAD_RV to the non-selected word line. Thus, the channel within the non-selected sub-block is in the floating state, and the potential of the channel is boosted by the voltage VREAD_RV of the non-selected word line, and is increased to a voltage Vch_usrp. Thus, the voltage of the selected word line is the voltage VRV (0 V) and the potential of the channel is the voltage Vch_usrp that is lower than the voltage Vch1 to which the reverse stress is applied. As a result, the reverse stress applied to the memory cell transistor within the non-selected sub-block is reduced.

3.3 Effect According to this Embodiment

In the embodiment described above, in the weak erase operation, a control signal to the select gate transistor within the non-selected sub-block and the voltage applied to the word line are adjusted, whereby it is possible to reduce the reverse stress applied to the memory cell transistor of the non-selected sub-block.

In the first example illustrated in FIG. 17, a control waveform in which the word line is set up in two stages is employed and the select gate transistor SGDTr within the non-selected sub-block is in the ON state during the period until the voltage Vmid is applied to the word line WL. Thus, the potential of the channel within the non-selected sub-block is maintained to be the same voltage as that of the bit line. Thereafter, the select gate transistor SGDTr is in the OFF state and then the potential of the channel is boosted by coupling resulting from a reduced amplitude of the word line. The potential of the channel within the non-selected sub-block by the control method may be adjusted by adjusting the voltage Vmid such that excessive voltage stress is not applied to the memory cell transistor. Thus, it is possible to reduce a defect that strong the reverse stress is applied to the memory cell within the non-selected sub-block.

In the second example illustrated in FIG. 18, the select gate transistor SGDTr within the non-selected sub-block is in the OFF state in the period in which the voltage VREAD_RV or the voltage VRV is applied to the word line. Thus, the channel within the non-selected sub-block is in the electrically floating state and the potential of the channel is boosted, and is increased to the voltage Vch_usrp.

The difference between the potential Vch1 of the channel for the reverse stress in the selected sub-block and the potential Vch_usrp of the channel of the non-selected sub-block in this case is a difference of an initial charging potential of the time t7 to time t8. As described above, the initial charging potential is varied by the threshold of the memory cell transistor, the voltage level of the voltage VSGD, or the threshold of the select gate transistor SGDTr. In the selected sub-block, a relationship of Vch1>Vch_usrp is satisfied as a result of charging by “VSGD-Vt_SGD”. Thus, also in this state, it is possible not to apply the reverse stress to the memory cell transistor of the non-selected sub-block strongly.

### 4. Modification Example and the Like

In the semiconductor memory device according to the embodiments described above, the first and second memory cells MTr, the first word line WL connected to the gates of the first and second memory cells, the first bit line BL electrically connected to one end of the first memory cell, and the second bit line BL electrically connected to one end of the second memory cell are provided. The write operation includes a plurality of loops (write cycle) and the loops include the program operation (first operation) for applying the write voltage, the weak erase operation (second operation) for applying the first voltage that is lower than the write voltage, and the program verify operation (third operation) for applying the verify voltage. When the threshold voltage of the first memory cell is smaller than the first threshold and the threshold voltage of the second memory cell is greater than or equal to the first threshold, in the weak erase operation, the voltage of the first bit line is applied to the first bit line and the voltage of the second bit line that is smaller than the voltage of the first bit line is applied to the voltage of the second bit line.

Furthermore, although a case where the embodiments described above are applied to the memory cell capable of storing one-bit data is exemplified, the embodiments may be applied to a memory cell capable of storing n-bit (n is a natural number of 2 or more) data.

Furthermore, in the embodiments described above, although the three-dimensional stacked NAND-type flash memory is exemplified as the semiconductor memory device, the semiconductor memory device is not limited to the three-dimensional stacked type and the embodiments may be applied to a NAND-type flash memory in which the memory cells are two-dimensionally arranged within a plane of the semiconductor substrate and the like. Furthermore, the embodiments described above are not limited to the NAND-type flash memory and may be applied to other memory devices in general.

Furthermore, the embodiments may be implemented by itself, or they may be implemented in a combination in which a plurality of the embodiments may be combined. For example, the second and third embodiments may be also applied to each of the first to the third examples described in the first embodiment.

Furthermore, as another control method of the weak erase operation in the embodiments, although there is a method of uniformly performing the weak erase operation with respect to not only the memory cell transistor that does not pass the program verify operation, also the memory cell transistor that passes the program verify operation. In such a case, the positive voltage is applied to all the bit lines BL regardless whether or not the program verify operation was passed. Thus, the drain-side select transistor is in the OFF state, the weak erase operation of the memory cell transistor is in the floating state, whereby the potential of the channel is boosted by the voltage VREAD_RV of the non-selected word line and is increased to the voltage Vch. As a result, since the voltage of the selected word line is 0 V and the potential of the channel of the memory cell transistor is the voltage Vch, it is possible to uniformly apply the reverse stress to the memory cell transistor that passes the program verify operation and the memory cell transistor that does not pass the program verify operation.

Moreover, in each embodiment,

(1) In the read operation, when the embodiment is applied to the memory cell capable of storing 2-bit data,

a voltage applied to the word line that is selected for the read operation of A level is, for example, between 0 V and 0.55 V. This is not limiting and the voltage may be any of between 0.1 V and 0.24 V, 0.21 V and 0.31 V, 0.31 V and 0.4 V, 0.4 V and 0.5 V, and 0.5 V and 0.55 V.

A voltage applied to the word line that is selected for the read operation of B level is, for example, between 1.5 V and 2.3 V. This is not limiting and the voltage may be any of between 1.65 V and 1.8 V, 1.8 V and 1.95 V, 1.95 V and 2.1 V, and 2.1 V and 2.3 V.

A voltage applied to the word line that is selected for the read operation of C level is, for example, between 3.0 V and 4.0 V. This is not limiting and the voltage may be any of between 3.0 V and 3.2 V, 3.2 V and 3.4 V, 3.4 V and 3.5 V, 3.5 V and 3.6 V, and 3.6 V and 4.0 V.

As a time (tR) of the read operation, for example, it may be between 25 μs and 38 μs, 38 μs and 70 μs, and 70 μs and 80 μs.

(2) The write operation includes the program operation, the weak erase operation, and verify operation. In the write operation,

a voltage initially applied to the word line selected during the program operation is, for example, between 13.7 V and 14.3 V. This is not limiting and the voltage may be, for example, any of between 13.7 V and 14.0 V, and 14.0 V and 14.6 V. A voltage initially applied to the word line selected when writing odd-numbered word lines and a voltage initially applied to the word line selected when writing even-numbered word lines may be changed.

When the program operation is an Incremental Step Pulse Program (ISPP) type, as a voltage of step-up, approximately 0.5 V is exemplified.

As the voltage applied to the non-selected word line, for example, it may between 6.0 V and 7.3 V. This is not limiting and the voltage may be, for example, between 7.3 V and 8.4 V, or 6.0 V or less.

A pass voltage to apply may be changed depending on whether the non-selected word line is the odd-numbered word line or the even-numbered word line. A time (tProg) of the write operation may be, for example, between 1,700 μs and 1,800 μs, 1,800 μs and 1,900 μs, and 1,900 μs and 2,000 μs.

(3) In the erase operation (except the weak erase operation),

a voltage initially applied to a wafer which is formed in an upper portion of the semiconductor substrate and on which the memory cells are arranged is, for example, between 12 V and 13.6V. This is not limiting and the voltage may be between 13.6 V and 14.8 V, 14.8 V and 19.0 V, 19.0 V and 19.8 V, and 19.8 V and 21 V. A time (tErase) of the erase operation may be, for example, between 3,000 μs and 4,000 μs, 4,000 μs and 5,000 μs, and 4,000 μs and 9,000 μs.

(4) In the structure of the memory cell,

the charge storage layer is arranged on the semiconductor substrate (silicon substrate) through the tunnel insulating film of which a film thickness is 4 nm to 10 nm. The charge storage layer may have a stacked structure of an insulating film of SiN, SiON, and the like of which a film thickness is 2 nm to 3 nm, and polysilicon of which a film thickness is 3 nm to 8 nm. Furthermore, metal such as Ru may be added to polysilicon. An insulating film is provided on the charge storage layer. For example, the insulating film includes a silicon oxide film of which a film thickness is 4 nm to 10 nm, which is interposed between a lower layer High-k film of which a film thickness is 3 nm to 10 nm and an upper layer High-k film of which a film thickness is 3 nm to 10 nm. The High-k film may be HfO and the like. In addition, film thickness of the silicon oxide film may be thicker than film thickness of the High-k film. A control electrode of which a film thickness 30 nm to 70 nm is formed on the insulating film through a material having a film thickness is 3 nm to 10 nm. The material may be a metal oxide film such as TaO and a metal nitride film such as TaN. For the control electrode, Wand the like may be used.

Furthermore, it is possible to form an air gap between the memory cells.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a first memory cell;
a first word line electrically connected to a gate of the first memory cell;
a first bit line electrically connected to one end of the first memory cell; and
a controller configured to execute a write operation, which includes a plurality of cycles including a first cycle and a second cycle that is executed after the first cycle, wherein
the first cycle includes a first operation of applying a program voltage to the first word line, a second operation executed after the first operation of applying a first voltage to the first bit line and a second voltage lower than the first voltage to the first word line, and a third operation executed after the second operation of applying a verify voltage to the first word line, and
the second cycle includes the first operation and then the third operation, and excludes the second operation.

2. The device according to claim 1, further comprising:
a second memory cell having a gate to which the first word line is electrically connected; and
a second bit line electrically connected to one end of the second memory cell, wherein
the second cycle further includes a fourth operation of applying a third voltage to the second bit line and the second voltage to the first word line, the third voltage being lower than the first voltage, the fourth operation being executed between the first and third operations.

3. The device according to claim 2, further comprising:
a third memory cell; and
a second word line electrically connected to a gate of the third the memory cell, wherein
a pass voltage lower than the program voltage is applied to the second word line in the first operation, a fourth voltage higher than the first voltage is applied to the second word line in the second operation and the fourth operation, and a read voltage higher than the verify voltage is applied to the second word line in the third operation.

4. The device according to claim 3, further comprising:
a first select transistor arranged between one end of the first memory cell and the first bit line;
a second select transistor arranged between one end of the second memory cell and the second bit line;
a fourth memory cell having a gate electrically connected to the first word line; and
a third select transistor arranged between one end of the fourth memory cell and the first bit line, wherein
in the second operation, a fifth voltage is applied to the gates of the first select transistor and the second select transistor, and a sixth voltage to a gate of the third select transistor.

5. The device according to claim 4, wherein
wherein in a state where the fifth voltage is applied to the gates of the first and second select transistors,
the first select transistor is in a non-conductive state and a channel potential of the first memory cell and a potential of the first bit line are different,
the second select transistor is in a conductive state so that a channel potential of the second memory cell is at the third voltage.

6. The device according to claim 5, wherein
at a start of the second operation, a seventh voltage higher than the fifth voltage is applied to the gate of the third select transistor so that the third select transistor is in the conductive state.

7. The device according to claim 6, wherein
the seventh voltage is maintained for a period of time to boost a voltage of the first word line, and then, the sixth voltage lower than the seventh voltage is applied to the gate of the third select transistor, so that the third select transistor is in the non-conductive state.

8. The device according to claim 4, wherein the sixth voltage is lower than the fifth voltage.

9. The device according to claim 1, wherein the second voltage is lower than a source line voltage.

10. The device according to claim 1, further comprising:
a row decoder that supplies voltages to the first and second word lines.

11. A method of executing a write operation in a semiconductor memory device that includes a first memory cell, a first word line electrically connected to a gate of the first memory cell, and a first bit line electrically connected to one end of the first memory cell, said method comprising:
executing the write operation in multiple cycles including a first cycle and a second cycle that is executed after the first cycle, wherein
the first cycle includes a first operation of applying a program voltage to the first word line, a second operation executed after the first operation of applying a first voltage to the first bit line and a second voltage lower than the first voltage to the first word line, and a third operation executed after the second operation of applying a verify voltage to the first word line, and
the second cycle includes the first operation and then the third operation, and excludes the second operation.

12. The method according to claim 11, wherein the semiconductor memory device further includes a second memory cell having a gate to which the first word line is electrically connected, and a second bit line electrically connected to one end of the second memory cell, wherein
the second cycle further includes a fourth operation of applying a third voltage to the second bit line and the second voltage to the first word line, the third voltage being lower than the first voltage, the fourth operation being executed between the first and third operations.

13. The method according to claim 12, wherein the semiconductor memory device further includes a third memory cell, and a second word line electrically connected to a gate of the third memory cell, wherein
a pass voltage lower than the program voltage is applied to the second word line in the first operation, a fourth voltage higher than the first voltage is applied to the second word line in the second operation and the fourth operation, and a read voltage higher than the verify voltage is applied to the second word line in the third operation.

14. The method according to claim 13, wherein the semiconductor memory device further includes a first select transistor arranged between one end of the first memory cell and the first bit line, a second select transistor arranged between one end of the second memory cell and the second bit line, a fourth memory cell having a gate electrically connected to the first word line, and a third select transistor arranged between one end of the fourth memory cell and the first bit line, wherein
in the second operation, a fifth voltage is applied to the gates of the first select transistor and the second select transistor, and a sixth voltage to a gate of the third select transistor.

15. The method according to claim 14, wherein
wherein in a state where the fifth voltage is applied to the gates of the first and second select transistors,
the first select transistor is in a non-conductive state and a channel potential of the first memory cell and a potential of the first bit line are different,
the second select transistor is in a conductive state so that a channel potential of the second memory cell is at the third voltage.

16. The method according to claim 15, wherein
at a start of the second operation, a seventh voltage higher than the fifth voltage is applied to the gate of the third select transistor so that the third select transistor is in the conductive state.

17. The method according to claim 16, wherein
the seventh voltage is maintained for a period of time to boost a voltage of the first word line, and then, the sixth voltage lower than the seventh voltage is applied to the gate of the third select transistor, so that the third select transistor is in the non-conductive state.

18. The method according to claim 14, wherein the sixth voltage is lower than the fifth voltage.

19. The method according to claim 11, wherein the second voltage is lower than a source line voltage.

20. The method according to claim 11, further comprising:
verifying that a threshold voltage of the first memory cell exceeds a first threshold in the third operation of the first cycle.
